(19) United States
(12) Patent Application Publication
(10) Pub. No.: US 2006/0171243 A1
(43) Pub. Date: Aug. 3, 2006

(54) MEMORY ARRAY CIRCUIT WITH WORD LINE TIMING CONTROL FOR READ OPERATIONS AND WRITE OPERATIONS

(76) Inventor: Atsushi Kawasumi, Kawasaki (JP)

Correspondence Address: WATCHSTONE P + D, 1300 EYE STREET, NW, SUITE 400 EAST TOWER, WASHINGTON, DC, 20005, US

(21) Appl. No.: 10/906,037

(22) Filed: Jan. 31, 2005

(51) Int. Cl. G11C 8/00

(52) U.S. Cl. 365/233

(57) ABSTRACT

A timing controller for a memory cell circuit provides separate sense amplifier timing signals and write circuit timing signals during respective read and write cycles of the memory cell circuit. Timing of word line read enable signals is different than timing of word line write enable signals, and is correlated with the sense amplifier timing and write circuit timing signals. Improved circuit performance is achieved by providing the separately generated timing signals for read operations and for write operations of the memory cell circuit.

### FIELD OF THE INVENTION

The present invention relates generally to solid state memory devices, such as semiconductor memory arrays, and more particularly to read/write control circuits for such arrays.

### BACKGROUND OF THE INVENTION

Computer systems utilize a data processor, such as a CPU, that is coupled to one or more memory devices, such as semiconductor memory cell arrays, via a memory controller circuit. The processor regularly exchanges information in the form of binary digits or “bits” with the memory devices during operation, both reading stored bits from and writing processed bits to the memory devices using the memory controller circuit.

A conventional memory device, such as a random access memory (“RAM”) device, typically includes a memory array composed of a plurality of memory cells arranged in rows and columns. Generally, to write a data bit into a specified memory cell of the memory array, the memory controller provides the data bit to an input buffer of the memory device in response to an internal clock signal. In response to a data clock signal provided to the memory device by the memory controller, the data bit is then latched into the memory array. For reliable transfer of data to the memory array, there must be a sufficient time delay between the internal clock of the memory controller and the data clock signal, such that sampling of the data bit at the input buffer takes place at a time when the data bit is stable.

Similarly, to read a data bit out of a specified memory cell of the memory array, the data bit is latched from the memory array to an output buffer in response to a data clock signal provided to the memory device by the memory controller. The data bit then is latched into the memory controller in response to the internal clock signal of the memory controller. To insure that the data bit is sampled by the memory controller at a time when the bit value is stable, a sufficient time delay between the data clock signal and the internal clock signal of the memory controller must be provided.

In the background art, the timing between the activation/disable of the data clock signal (which is typically applied to a word line of the memory cell array) and the internal clock of the memory controller circuit is identical for both read and write operations. However, because the requirements for read operations are different than the requirements for write operations, the conventional timing scheme does not represent an optimized circuit performance.

For example, in a read operation, disabling of the word line must await completion of bit line read signal development, which is important for proper operation of sense amplifier circuits. However, in a write operation larger currents are involved for the purpose of driving the bit values into the memory cell, and consequently bit line write signal development completes faster than bit line read signal development. As a consequence, the speed of write operations is hindered by the word line disable timing requirement for read operations, resulting in slower write operation than might be possible.

In particular, as shown in FIG. 1, before a typical read cycle, the bit line (BL READ) for a memory cell is pre-charged to the V_{DD} level. During the read cycle, when word line WL is activated by a data clock signal, as the cell is read, the bit line voltage is pulled down by an amount typically 100 mV to 200 mV by a current typically of approximately 100 μA as indicated by reference line Vr. Once the read cycle has completed, pre-charging starts until the bit line is again fully pre-charged back to the V_{DD} level as shown. At such a time, the read cycle can begin again. The time required for the pre-charging of the bit line is significantly smaller than the time needed for the bit line to transition from reference point A to reference point B, because the bit line typically only needs to be charged up by approximately 100-200 mV.

In contrast, the bit line timing (BL WRITE) during a write cycle is significantly different than that of a read cycle. Similar to the read cycle, the bit line (BL WRITE) before a typical write cycle is pre-charged to the VDD level as shown in FIG. 1. During the write cycle the bit line is pulled down to ground level GND, and the write cycle is complete when the bit line voltage reaches ground. However, in the background art, pre-charging of the bit line does not begin until the time when a read cycle is complete, because the identical word line disable timing for both read and write operations means that word line disabling must be delayed by an amount D until the bit line read signal development is completed.

Consequently, there exists a need in the art to improve semiconductor memory array circuit performance by providing a memory device that provides a shorter write cycle time.

### SUMMARY OF THE INVENTION

The present invention eliminates the shortcomings in the background art and provides a significant advance in the art, by providing according to one embodiment, a memory cell circuit, comprising an array of addressable memory cells, each coupled to a respective word line and to a pair of respective bit lines, a sense amplifier coupled to the bit lines for reading data stored in the memory cells, a write circuit coupled to the bit lines for writing data into the memory cells, and a timing controller for providing a sense amplifier enable signal to an enable input of the sense amplifier during a read cycle of the memory cell circuit, for providing a write circuit enable signal to an enable input of the write circuit during a write cycle of the memory cell circuit, and providing word line read enable signals to the word lines during the read cycle, and word line write enable signals to the word lines during the write cycle, wherein timing of the word line read enable signals is different than timing of the word line write enable signals, and is correlated to the respective timing of the sense amplifier operation and write circuit operation.

In some embodiments, the sense amplifier enable signal is correlated with the word line read enable signal.

In some embodiments, the write circuit enable signal is correlated with the word line write enable signal.

In some embodiments, the sense amplifier enable signal is coupled to the word line read enable signal.

In some embodiments, the write circuit enable signal is coupled to the word line write enable signal.

In some embodiments, the timing controller comprises a logic OR circuit having an output terminal coupled to the word lines, and input terminals respectively coupled to separate read clock and write clock signals.

In some embodiments, word line address circuits are coupled between the word lines and the timing controller output terminal.

According to another embodiment of the invention, a method of controlling a memory cell circuit is provided, including the steps of providing a read operation timing signal to a word line of the circuit during a read cycle, the read operation timing signal being correlated to a sense amplifier timing signal of a sense amplifier that detects stored information read from the memory cell circuit; and providing a write operation timing signal to a word line of the circuit during a write cycle, the write operation timing signal being correlated to a write circuit timing signal of a write circuit that writes information into the memory cell circuit.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The various embodiments of the present invention are shown by way of example, and not limitation, in the accompanying figures, in which:

FIG. 1 is a timing diagram of a memory cell array read/write operation according to the conventional art;

FIG. 2 is a circuit diagram of a memory cell array circuit according to one example embodiment of the present invention; and

FIG. 3 is a timing diagram of a memory cell array read operation and write operation according to one example embodiment of the present invention.

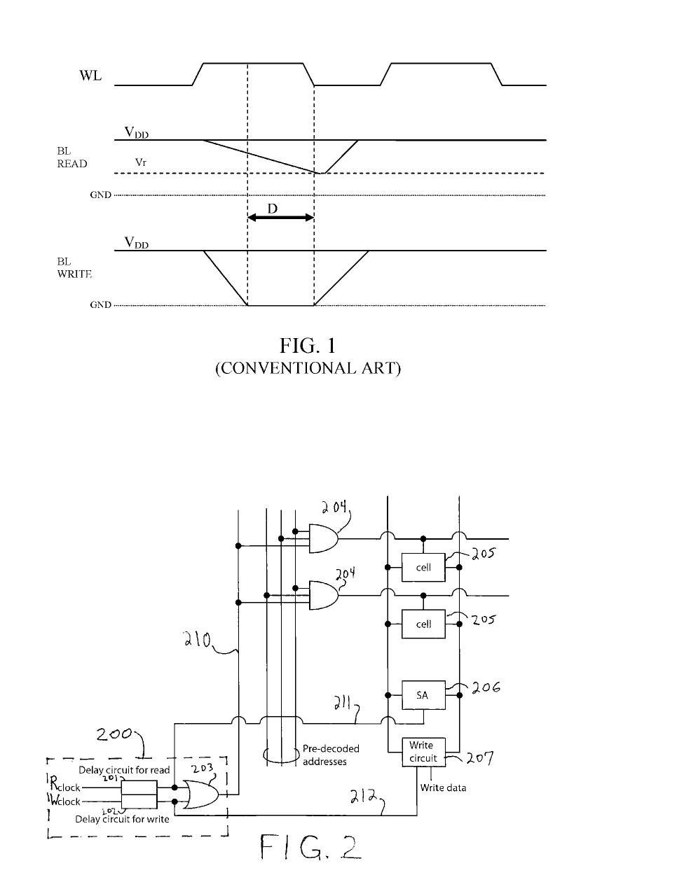

### DETAILED DESCRIPTION OF THE ILLUSTRATED EMBODIMENTS

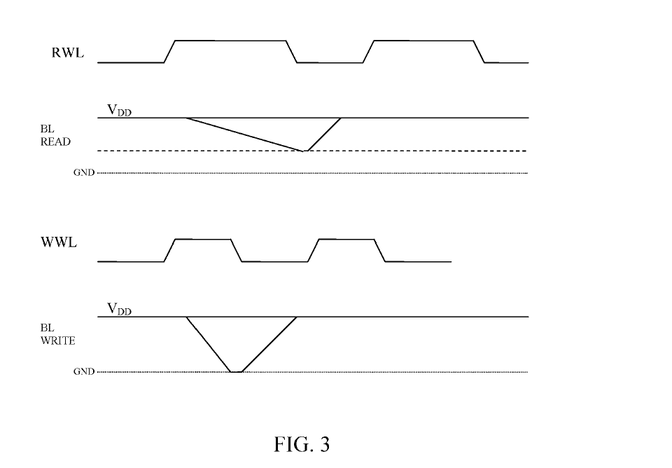

As shown in FIG. 2, according to one embodiment of the invention, a memory cell array circuit is provided with a timing controller 200 that implements separating timing signal generation for read operations and for write operations.

According to the illustrated embodiment, timing controller 200 is fed with a read clock R_{clock} and a write clock W_{clock}. Different delays 201 and 203 for a read operation and for a write operation also may be provided. The separate clock signals are inputted to a logic OR gate 203. The output of the OR gate 203 is provided to first inputs of word line addressing AND gates 204, the other inputs of which are coupled to a word line address bus. Consequently, an addressed word line will be activated when the output of the OR gate 203 is a logic high, in other words when either the read clock R_{clock} or the write clock W_{clock} is a high level.

The read clock R_{clock} also is provided over signal line 211 to an enable terminal of sense amplifier circuit 206, which senses bit values read out of memory cells 205 during a read operation and detects such values by sensing small voltage differences between the bit lines.

The write clock W_{clock} also is provided over signal line 212 to an enable terminal of a write circuit 207, which writes data into selected memory cells 205 in accordance with write data provided to the write circuit 207 at a write data input terminal.

As shown in FIG. 3, different word line activation/disable signals are provided to the word lines coupled to the outputs of address circuits 204, depending upon whether a read cycle or a write cycle is occurring. During a read operation, word line enable signal RWL is applied to the word lines, which is tailored to the characteristics of the read operation voltage transitions on the bit lines as shown by line BL READ.

On the other hand, during a write operation, word line enable signal WWL is applied to the word lines, which is tailored to the characteristics of the write operation voltage transitions on the bit lines as shown by line BL WRITE.

In this way, the circuit performance of the memory cell array circuit is optimized to have a high performance factor. By providing separate timing generation for read operations and for write operations, the read operation word line timing is correlated to the sense amplifier timing of the sense amplifier 206, and the write operation word line timing is correlated to the write circuit timing of the write circuit 207. This implementation also increases the timing margin, and also may be useful for circuit debugging operations.

While the present invention may be embodied in many different forms, a number of illustrative embodiments are described herein with the understanding that the present disclosure is to be considered as providing examples of the principles of the invention and that such examples are not intended to limit the invention to illustrative embodiments described herein and/or illustrated herein.

### BROAD SCOPE OF THE INVENTION

While illustrative embodiments of the invention have been described herein, the present invention is not limited to the various illustrative embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims (e.g., including that to be later added) are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure, the following abbreviated terminology may be employed: “e.g.” which means “for example;” and “NB” which means “note well” (nota bene).

What is claimed is:

1. A memory cell circuit, comprising:
an array of addressable memory cells, each coupled to a respective word line and to a pair of respective bit lines;
a sense amplifier coupled to said bit lines for reading data stored in said memory cells;
a write circuit coupled to said bit lines for writing data into said memory cells; and
a timing controller for providing a sense amplifier enable signal to an enable input of said sense amplifier during a read cycle of said memory cell circuit, for providing a write circuit enable signal to an enable input of said write circuit during a write cycle of said memory cell circuit, and providing word line read enable signals to said word lines during said read cycle, and word line write enable signals to said word lines during said write cycle;
wherein timing of said word line read enable signals is different than timing of said word line write enable signals.

2. The memory cell circuit of claim 1, wherein said sense amplifier enable signal is correlated with said word line read enable signal.

3. The memory cell circuit of claim 1, wherein said write circuit enable signal is correlated with said word line write enable signal.

4. The memory cell circuit of claim 1, wherein said sense amplifier enable signal is coupled to said word line read enable signal.

5. The memory cell circuit of claim 1, wherein said write circuit enable signal is coupled to said word line write enable signal.

6. The memory cell circuit of claim 1, wherein said timing controller comprises a logic OR circuit having an output terminal coupled to said word
lines, and input terminals respectively coupled to separate read clock and write clock signals.

7. The memory cell circuit of claim 6, further comprising word line address circuits coupled between said word lines and said timing controller output terminal.

8. A memory cell circuit, comprising:
an array of addressable memory cells, each coupled to a respective word line and to a pair of respective bit lines;
a sense amplifier coupled to said bit lines for reading data stored in said memory cells;
a write circuit coupled to said bit lines for writing data into said memory cells; and
a timing controller for providing a sense amplifier enable signal to an enable input of said sense amplifier during a read cycle of said memory cell circuit, for providing a write circuit enable signal to an enable input of said write circuit during a write cycle of said memory cell circuit, and providing word line read enable signals to said word lines during said read cycle, and word line write enable signals to said word lines during said write cycle;
wherein said timing controller comprises a logic OR circuit having an output terminal coupled to said word lines, and input terminals respectively coupled to separate read clock and write clock signals.

9. The memory cell circuit of claim 8, wherein said sense amplifier enable signal is correlated with said word line read enable signal.

10. The memory cell circuit of claim 8, wherein said write circuit enable signal is correlated with said word line write enable signal.

11. The memory cell circuit of claim 8, wherein said sense amplifier enable signal is coupled to said word line read enable signal.

12. The memory cell circuit of claim 8, wherein said write circuit enable signal is coupled to said word line write enable signal.

13. The memory cell circuit of claim 8, further comprising word line address circuits coupled between said word lines and said timing controller output terminal.

14. A method of controlling a memory cell circuit, comprising the steps of:
providing a read operation timing signal to a word line of said circuit during a read cycle, said read operation timing signal being correlated to a sense amplifier timing signal of a sense amplifier that detects stored information read from said memory cell circuit; and
providing a write operation timing signal to a word line of said circuit during a write cycle, said write operation timing signal being correlated to a write circuit timing signal of a write circuit that writes information into said memory cell circuit.

15. The method of claim 14, wherein said sense amplifier timing signal is correlated with said word line read operation timing signal.

16. The method of claim 14, wherein said write circuit timing signal is correlated with said word line write operation timing signal.

17. The method of claim 14, wherein said sense amplifier timing signal is coupled to said word line read operation timing signal.

18. The method of claim 14, wherein said write circuit timing signal is coupled to said word line write operation timing signal.
